(19) United States
(12) Patent Application Publication
(10) Pub. No.: US 2010/0239982 A1
(43) Pub. Date: Sep. 23, 2010

(54) Photoresist composition with high etching resistance

(75) Inventors: Sang-Jun Choi, Seoul (KR); Youn-Jin Cho, Gyeonggi-do (KR); Seung-Wook Shin, Gyeonggi-do (KR); Hye-Won Kim, Seoul (KR)

Correspondence Address: LEE & MORSE, P.C., 3141 FAIRVIEW PARK DRIVE, SUITE 500, FALLS CHURCH, VA, 22042, US

(73) Assignee: Cheil Industries, Inc., Kyeongsangbuk-do (KR)

(21) Appl. No.: 12/801,146

(22) Filed: May 25, 2010

Related U.S. Application Data
(63) Continuation of application No. PCT/KR2007/007038, filed on Dec. 31, 2007.

(30) Foreign Application Priority Data
Nov. 26, 2007 (KR) 10-2007-0121122

(51) Int. Cl. G03F 7/004

(52) U.S. Cl. 430/286.1

(57) ABSTRACT

A resist composition includes a first polymer including a repeating unit having the following Chemical Formula 1 and a repeating unit having the following Chemical Formula 2, a second polymer including a repeating unit having the following Chemical Formula 3, a repeating unit having the following Chemical Formula 4, and a repeating unit having the following Chemical Formula 5, a photoacid generator, and a solvent.

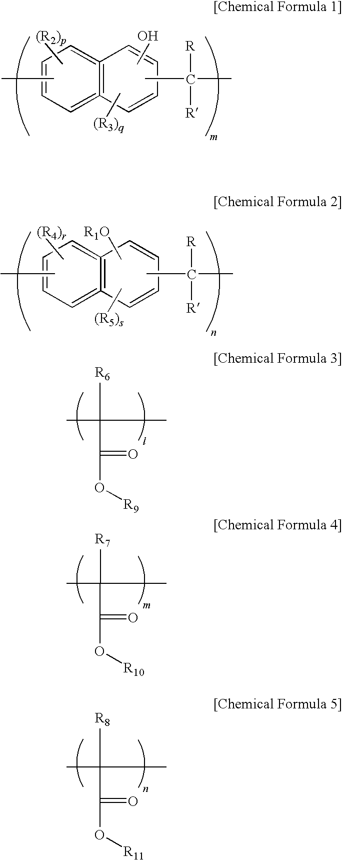

### CROSS-REFERENCE TO RELATED APPLICATION

This application is a continuation of pending International Application No. PCT/KR2007/007038, entitled “Photoresist Composition with High Etching Resistance,” which was filed on Sep. 22, 2008, the entire contents of which are hereby incorporated by reference.

### BACKGROUND

1. Field

The present invention relates to a resist composition having excellent etching resistance characteristics. More particularly, the present invention relates to a photosensitive resist composition that can be used under an exposure light source having an ultrashort wavelength region such as EUV of 13.5 nm as well as an ArF region of 193 nm.

2. Description of the Related Art

Complications of a semiconductor manufacturing process and integration of semiconductors have increasingly required forming a fine pattern. For example, a semiconductor device with a capacity of more than 16 gigabytes may have a pattern size of less than 70 nm according to a design rule.

For lithography, a photoresist material using a shorter wavelength, such as an ArF excimer laser of 193 nm, is preferred to one using a longer wavelength, such as a KrF excimer laser of 248 nm. An ArF resist may include an acryl-based or methacryl-based polymer. However, these polymers may exhibit poor dry etching resistance, i.e., the etch selectivity may be low, causing difficulties in performing a dry etching process using plasma gas during the semiconductor device manufacturing process.

### SUMMARY

It is a feature of an embodiment to provide a resist composition that may be prepared at low cost.

It is another feature of an embodiment to provide a resist composition that exhibits sufficient resistance for dry etching and excellent adhesion to an underlayer.

It is another feature of an embodiment to provide a resist composition that exhibits excellent lithography performance in a lithography process using an ultrashort wavelength region such as EUV of 13.5 nm as well as an ArF region such as 193 nm.

At least one of the above and other features and advantages may be realized by providing a resist composition, including a first polymer including a repeating unit having the following Chemical Formula 1 and a repeating unit having the following Chemical Formula 2, a second polymer including a repeating unit having the following Chemical Formula 3, a repeating unit having the following Chemical Formula 4, and a repeating unit having the following Chemical Formula 5, a photoacid generator, and a solvent,

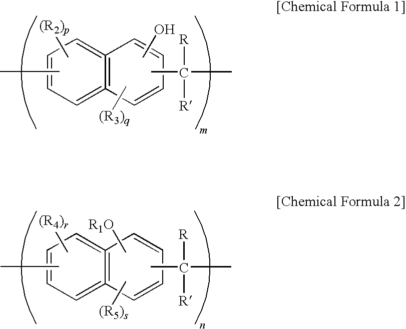

wherein, in the above Chemical Formulae 1 and 2, R₁ is a C4 to C20 acid-labile group, R₂ to R₅ are independently hydrogen or an alkyl, p, q, r, and s are independently an integer ranging from 1 to 3, R and R′ are independently hydrogen or an alkyl, and m and n are mole ratios of the repeating units, m/(m+n) being about 0.1 to 1,

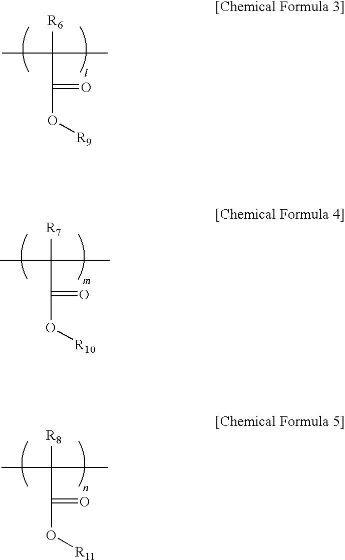

wherein, in the above Chemical Formulae 3 to 5, R₆ to R₈ are independently hydrogen or methyl, R₉ is a C4 to C20 acid-labile group, R₁₀ is a lactone-derived group, R₁₁ is hydrogen or an alkyl or cycloalkyl including a polar functional group selected from among a hydroxy, a carboxyl, and a combination thereof, and l, m and n are mole ratios of the repeating units, 1/(l+m+n) being about 0.1 to about 0.5, m/(l+m+n) being about 0.3 to about 0.5, and n/(l+m+n) being in the range of about 0.1 to about 0.4.

The first polymer may have a weight average molecular weight (Mw) of about 3,000 to about 20,000.

The acid-labile group R₉ may be norbornyl, isobornyl, cyclodecanyl, adamantyl, norbornyl having a lower alkyl substituent, isobornyl having a lower alkyl substituent, cyclodecanyl having a lower alkyl substituent, adamantyl having a lower alkyl substituent, alkoxycarbonyl, alkoxycarbonyl alkyl, amyloxycarbonyl, amyloxycarbonyl alkyl, 2-tetrahydropyranyloxycarbonyl alkyl, 2-tetrahydrofuranyloxycarbonyl alkyl, a tertiary alkyl, or an acetal.

The acid-labile group R₉ may be 2-methyl-2-norbornyl, 2-ethyl-2-norbornyl, 2-methyl-2-isobornyl, 2-ethyl-2-isobornyl, 8-methyl-8-tricyclodecanyl, 8-ethyl-8-tricyclodecanyl, 2-methyl-2-adamantyl, 2-ethyl-2-adamantyl, 2-propyl-2-adamantyl, t-butoxycarbonyl, t-butoxycarbonylmethyl, t-amyloxycarbonyl, t-amyloxycarbonylmethyl, 1-ethoxyethoxycarbonylmethyl, 2-tetrahydropyranyloxycarbonylalkyl, 2-tetrahydrofuranyloxycarbonylalkyl, t-butyl, triethylcarbyl, 1-methyl cyclohexyl, 1-ethylcyclopentyl, or t-amyl.

The lactone-derived group may be represented by the following Chemical Formula 6 or 7:

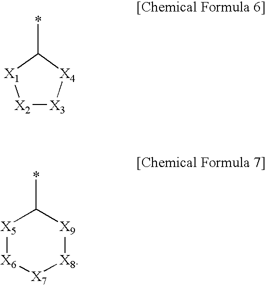

In the above Chemical Formula 6, at least two of X₁ to X₄ may be independently CO and O, and the remaining may be CR″, where R″ is hydrogen, an alkyl, or an alkylene forming a fused ring with the five-member ring, and, in the above Chemical Formula 7, at least two of X₅ to X₉ may be independently CO and O, the remaining are CR″, where R″ is hydrogen, an alkyl, or an alkylene forming a fused ring with the five-member ring, or all of X₅ to X₉ may be CR″′, where R″′ is hydrogen, an alkyl, an ester-containing alkylene forming a fused ring with the six-member ring, and at least two of R″′ are linked with each other to form a lactone ring.

The lactone-derived group may be butyrolactonyl, valerolactonyl, 1,3-cyclohexanecarbolactonyl, 2,6-norbornanecarbolacton-5-yl, or 7-oxa-2,6-norbornanecarbolacton-5-yl.

The alkyl or cycloalkyl including a polar functional group may be 2-hydroxyethyl or 3-hydroxy-1-adamantyl.

The second polymer may have a weight average molecular weight (Mw) of about 3,000 to about 30,000.

The first polymer may be included in an amount of about 5 to about 30 wt % based on the sum of the weights of the first polymer and the second polymer.

The photoacid generator may be included in an amount of about 1 to about 15 parts by weight based on 100 parts by weight of the first polymer and the second polymer.

The photoacid generator may include a triarylsulfonium salt, a diaryliodonium salt, a sulfonate, or a mixture thereof.

The photoacid generator may include triarylsulfonium triflate, diaryliodonium triflate, triarylsulfonium nonaflate, diaryliodonium nonaflate, succinimidyl triflate, 2,6-dinitrobenzyl sulfonate, or a mixture thereof.

The composition may further include about 0.1 to about 1.0 part by weight of an organic base based on 100 parts by weight of the first polymer and the second polymer.

The organic base may include triethylamine, triisobutylamine, trioctylamine, triisodecylamine, triethanolamine, or a mixture thereof.

### DETAILED DESCRIPTION

Korean Patent Application No. 10-2007-0121122, filed on Nov. 26, 2007, in the Korean Intellectual Property Office, and entitled: “Photoresist Composition with High Etching Resistance,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. In the drawing figures, the dimensions of layers and regions may be exaggerated for clarity of illustration. Like reference numerals refer to like elements throughout.

A resist composition according to an embodiment may include (a) a first polymer including repeating units represented by the following Chemical Formulae 1 and 2, (b) a second polymer including repeating units represented by the following Chemical Formulae 3 to 5, (c) a photoacid generator (PAG), and (d) a solvent.

First Polymer

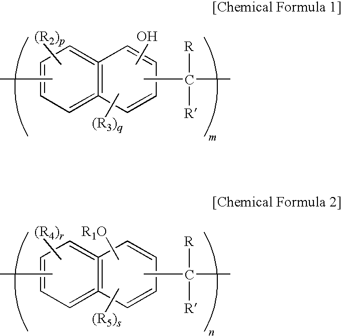

In the above Chemical Formulae 1 and 2, R₁ may be a C4 to C20 acid-labile group capable of being decomposed under an acid catalyst. Specific examples of the acid-labile group include tetrahydropyranyl, and an alkoxyalkyl such as 1-ethoxyethyl, 1-isopropyloxyethyl, or 1-isobutoxyethyl.

In the above Chemical Formulae 1 and 2, R₂ to R₅ may be independently hydrogen or an alkyl. R₂ to R₅ are preferably hydrogen or a C1 to C4 lower alkyl.

In the above Chemical Formulae 1 and 2, p, q, r, and s may be independently an integer ranging from 1 to 3.

In the above Chemical Formulae 1 and 2, R and R′ may be independently hydrogen or an alkyl. R and R′ are preferably hydrogen or a C1 to C4 lower alkyl.

In the above Chemical Formulae 1 and 2, m and n are mole ratios of the repeating units, and m/(m+n) may be about 0.1 to 1.

Second Polymer

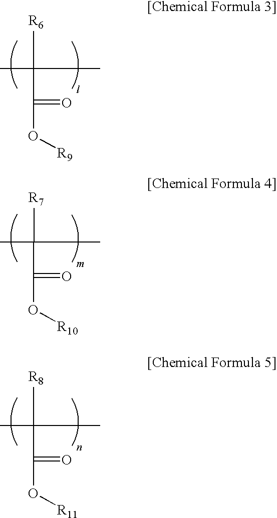

In the above Chemical Formulae 3 to 5, R₆ to R₈ may be independently hydrogen or methyl.

In the above Chemical Formulae 3 to 5, R₉ may be a C4 to C20 acid-labile group capable of being decomposed under an acid catalyst. R₉ is preferably norbornyl, isobornyl, cyclodecanyl, adamantyl, norbornyl having a lower alkyl substituent, isobornyl having a lower alkyl substituent, cyclodecanyl having a lower alkyl substituent, adamantyl having a lower alkyl substituent, alkoxycarbonyl, alkoxycarbonyl alkyl, amyloxycarbonyl, amyloxycarbonyl alkyl, 2-tetrahydropyranyloxycarbonyl alkyl, 2-tetrahydrofuranyloxycarbonyl alkyl, a tertiary alkyl, or an acetal. More preferably, R₉ is 2-methyl-2-norbornyl, 2-ethyl-2-norbornyl, 2-methyl-2-isobornyl, 2-ethyl-2-isobornyl, 8-methyl-8-tricyclodecanyl, 8-ethyl-8-tricyclodecanyl, 2-methyl-2-adamantyl, 2-ethyl-2-adamantyl, 2-propyl-2-adamantyl, t-butoxycarbonyl, t-butoxycarbonylmethyl, t-amyloxycarbonyl, t-amyloxycarbonylmethyl, 1-ethoxyethoxycarbonylmethyl, 2-tetrahydropyranyloxycarbonylalkyl, 2-tetrahydrofuranyloxycarbonylalkyl, alkoxycarbonylalkyl, amyloxycarbonyl, amyloxycarbonylalkyl, 2-tetrahydropyranyloxycarbonylalkyl, 2-tetrahydrofuranyloxycarbonylalkyl, t-butyl, triethylcarbyl, 1-methyl cyclohexyl, 1-ethylcyclopentyl, or t-amyl.

In the above Chemical Formulae 3 to 5, R₁₀ may be a lactone-derived group. R₁₀ is preferably a lactone-derived group represented by the following Formula 6 or 7. More preferably, R₁₀ is isobutyrolactonyl, valerolactonyl, 1,3-cyclohexanecarbolactonyl, 2,6-norbornanecarbolacton-5-yl, or 7-oxa-2,6-norbornanecarbolacton-5-yl.

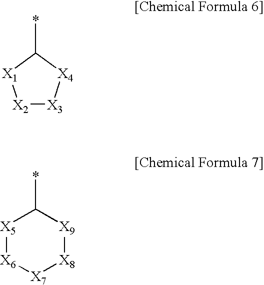

In the above Formula 6, at least two of X₁ to X₄ may be independently CO and O, and the remaining group except CO and O may be CR″ (where R″ is hydrogen, an alkyl, or an alkylene forming a fused ring with the five-member ring).

In the above Formula 7, at least two of X₅ to X₉ may be independently CO and O, the remaining group except CO and O may be CR″ (where R″ is hydrogen, an alkyl, or an alkylene forming a fused ring with the five-member ring). In another implementation, in the above Formula 7, all of X₅ to X₉ may be CR″′ (where R″′ is hydrogen, an alkyl, or an ester-containing alkylene forming a fused ring with the six-member ring), and at least two R″′ may be linked to each other to form a lactone ring.

In the above Chemical Formulae 3 to 5, R₁₁ may be hydrogen, or an alkyl, or a cycloalkyl including a polar functional group selected from the group consisting of a hydroxy, a carboxyl, or a combination thereof R₁₁ is preferably 2-hydroxyethyl or 3-hydroxy-1-adamantyl.

In the above Chemical Formulae 3 to 5, l, m, and n are mole ratios of the repeating units. In the above Chemical Formulae 3 to 5, l/(l+m+n) may be about 0.1 to about 0.5, m/(l+m+n) may be about 0.3 to about 0.5, and n/(l+m+n) may be about 0.1 to about 0.4.

As used herein, when specific definition is not otherwise provided, the term “substituted” may refer to one substituted with at least a substituent selected from the group consisting of a hydroxy, a halogen, a substituted or unsubstituted linear or branched alkyl, a substituted or unsubstituted cycloalkyl, a substituted or unsubstituted heterocycloalkyl, a substituted or unsubstituted alkoxy, a substituted or unsubstituted aryl, a substituted or unsubstituted heteroaryl, and a substituted or unsubstituted alkenyl.

As used herein, when specific definition is not otherwise provided, “an alkyl” may refer to a C1 to C20 alkyl, preferably a C1 to C12 alkyl, “a lower alkyl” may refer to a C1 to C4 alkyl, “an alkoxy” may refer to a C1 to C20 alkoxy, preferably a C1 to C12 alkoxy, “an alkenyl” may refer to a C2 to C20 alkenyl, preferably a C2 to C12 alkenyl, “an alkylene” may refer to a C1 to C20 alkylene, preferably a C1 to C12 alkylene, “an aryl” may refer to a C6 to C20 aryl, preferably a C6 to C12 aryl, “a heteroaryl” may refer to a C2 to C20 heteroaryl, preferably a C2 to C12 heteroaryl, “a cycloalkyl” may refer to a C3 to C20 cycloalkyl, preferably a C5 to C15 cycloalkyl, and “a heterocycloalkyl” may refer to a C2 to C20 heterocycloalkyl, preferably a C3 to C10 heterocycloalkyl. In the present specification, “heteroaryl” and “heterocycloalkyl” may refer to one including 1 to 3 heteroatoms selected from the group consisting of nitrogen (N), oxygen (O), sulfur (S), and phosphorus (P), and remaining carbon.

The first and the second polymers may respectively have a weight average molecular weight (Mw) of about 3,000 to about 30,000. In addition, they may have a polydispersity (Mw/Mn) of about 1.5 to about 2.5. They may have excellent etching resistance and resolution in the above ranges.

In addition, the first polymer may be a random, block, or graft copolymer including a repeating unit of Chemical Formulae 1 and 2. The second polymer may be a random, block, or graft copolymer including Chemical Formulas 3 to 5.

The first polymer including a repeating unit of the above Formulae 1 and 2 may be prepared by introducing a compound of Chemical Formula 2 with an acid-labile group having a decomposition reaction under an acid catalyst into a basic resin of Chemical Formula 1 through a polymer reaction. The basic resin may be prepared from, e.g., a copolymer of a naphthol monomer and paraformaldehyde.

According to an embodiment, the first polymer may be included in an amount of about 5 to about 30 wt % based on the entire amount of the first and second polymers. The second polymer may be included in an amount of about 95 to about 70 wt % based on the entire amount of the first and second polymers. Maintaining the amount of the first polymer at about 5 wt % or more may enhance resistance for dry etching. Maintaining the amount of the first polymer at about 30 wt % or less may avoid decreases in the transmission of the resist composition.

Photoacid Generator

The photoacid generator (c) may include sulfonium salts or iodonium salts, e.g., triarylsulfonium salts, diaryliodonium salts, sulfonates, or a mixture thereof. Preferably, the photoacid generator may include triarylsulfonium triflate, diaryliodonium triflate, triarylsulfonium nonaflate, diaryliodonium nonaflate, succinimidyl triflate, 2,6-dinitrobenzyl sulfonate, or a mixture thereof. The photoacid generator may be included in an amount of about 1 to about 15 parts by weight based on 100 parts by weight of the entire amount of the first and second polymers.

Maintaining the amount of the photoacid generator at about 1 part by weight or more may help avoid the exposure amount being excessive with respect to the resist composition. Maintaining the amount of the photoacid generator at about 15 parts by weight or less may help avoid decreases in the transmission of the resist composition.

Solvent

The solvent (d) may include, e.g., propylene glycol monomethyl ether acetate (PGMEA), propylene glycol methyl ether (PGME), ethyl lactate (EL), cyclohexanone, 2-heptanone, and the like. The solvent may be included in the composition as the balance. In an implementation, the solvent may be included in an amount of about 80 wt % to about 95 wt % based on the entire amount of the resist composition.

The resist composition may further include an organic base (amine quencher) in order to control the exposure amount and to form a resist profile. For example, the organic base may include triethylamine, triisobutylamine, trioctylamine, triisodecylamine, triethanolamine, or a mixture thereof. The organic base may be included in an amount of about 0.1 to about 1 parts by weight based on 100 parts by weight of the entire amount of the first and second polymers. Maintaining the amount of the organic base at about 0.1 parts by weight or more may help ensure that it provides the desired effect. Maintaining the amount of the organic base at about 1 part by weight or less may help avoid increase in the exposure amount required, and help ensure that a pattern is not formed.

A resist composition according to an embodiment may be used to form a pattern through the following example process.

A bare silicon wafer or a silicon wafer including an underlayer (such as a silicon oxide layer, a silicon nitride layer, or a silicon nitride oxide layer) on the upper surface may be treated with hexamethyldisilazane (HMDS) or coated with a bottom anti-reflective coating (BARC). Then, the resist composition according to an embodiment may be coated to be about 100 to about 150 nm thick on the silicon wafer.

The silicon wafer including the resist layer may be pre-baked (SB), e.g., at a temperature of about 90 to about 120° C. for about 60 to about 90 seconds, to remove the solvent, exposed to a light source (such as ArF or extreme UV (EUV), E-beam, and the like), and then post-exposure-baked, e.g., at a temperature of about 60 to about 120° C. for about 60 to about 90 seconds, in order to cause a chemical reaction within the exposure region of the resist layer.

Then, the resist layer may be developed, e.g., with a 2.38 wt % tetramethyl ammonium hydroxide solution. The exposed part of the resist layer may have a high solubility characteristic for a basic aqueous solution, and may thereby be easily dissolved and removed during the development process. When an ArF excimer laser is used as an exposure light source, a 70 to 90 nm-thick line and space pattern may be formed with a dose of about 5 to 50 mJ/cm².

The resist pattern obtained from the above process may be used as a mask, and the underlayer (such as a silicon oxide layer) may be etched by using an etching gas, e.g., a plasma of halogen gas or CₓF_{y} gas. Then, a silicon oxide layer pattern may be formed by removing the resist pattern remaining on the wafer, e.g., using a stripper.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to be construed as either limiting the scope of the invention as exemplified in the Examples or as necessarily being outside the scope of the invention in every respect.

### Polymers

### Synthesis Example 1

1 mol of 1-naphthol and 0.7 mol of paraformaldehyde were dissolved in a solvent of dioxane in a round bottom flask, and then 0.02 mol of para-toluenesulfonic acid (PTSA) was added thereto at room temperature. The resulting product was gradually heated to about 100° C. and then polymerized for 24 hours.

After the polymerization, the reactant was slowly precipitated in an excess amount of a water/methanol mixture. The precipitate was dissolved in an appropriate amount of tetrahydrofuran (THF) and then re-precipitated in an n-hexane/isopropyl alcohol mixture. Then, the acquired precipitate was dried in a 50° C. vacuum oven for about 24 hours, preparing a naphthol polymer (yield: 70%). Herein, the polymer had a weight average molecular weight (Mw) of 8,800 and a polydispersity (Mw/Mn) of 2.1.

### Synthesis Example 2

100 mmol of a naphthol polymer prepared according to Synthesis Example 1 and 60 mmol of ethylvinylether were dissolved in a solvent of dioxane. Then, para-toluene sulfonic acid was added to the solution in a catalytic amount. The resulting product was reacted at room temperature for about 12 hours.

After the reaction, the reactant was slowly precipitated in an excess amount of a water/methanol co-solvent. The precipitate was filtrated and then dissolved in an appropriate amount of THF and reprecipitated in a diethyl ether solvent. The precipitate was dried in a 50° C. vacuum oven for about 24 hours, preparing a polymer of the following Formula 8 (yield: 70%). Herein, the acquired polymer had a weight average molecular weight (Mw) of 9,800 and a polydispersity (Mw/Mn) of 2.1.

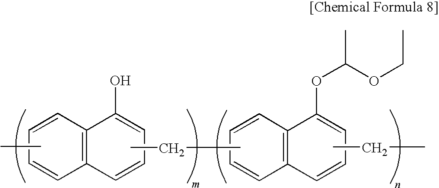

### Synthesis Example 3

100 mmol of the naphthol polymer of Synthesis Example 1 and 50 mmol of dihydropyran were dissolved in a dioxane solvent. The resulting solution was reacted according to the same method as in Synthesis Example 2, acquiring a polymer of the following Formula 9 (yield: 70%). Herein, the polymer had a weight average molecular weight (Mw) of 9,500 and a polydispersity (Mw/Mn) of 2.1.

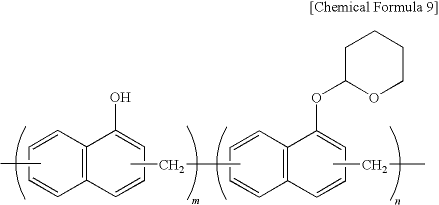

### Synthesis Example 4

40 mmol of 2-ethyl-2-adamantyl methacrylate, 40 mmol of γ-butyrolactonyl methacrylate, and 20 mmol of 3-hydroxy-1-adamantyl methacrylate were dissolved in a dioxane solvent in an amount of four times that of a monomer in a round bottom flask. Next, 8 mmol of azobisisobutyronitrile (AIBN) was added thereto. The resulting product was polymerized at a temperature of 80° C. for about 6 hours.

After the polymerization, the reactant was slowly precipitated in an excess amount of a diethyl ether solvent. The precipitate was filtrated and then dissolved in an appropriate amount of THF again and reprecipitated in diethyl ether. Then, the precipitate was dried at a 50° C. vacuum oven for about 24 hours, acquiring a polymer of the following formula 10 (yield: 75%). Herein, the polymer had a weight average molecular weight (Mw) of 15,800 and a polydispersity (Mw/Mn) of 1.8.

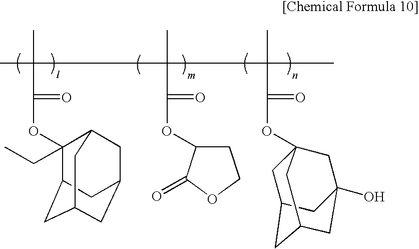

### Resist Compositions

### Examples 1 to 6

The naphthol polymers of Synthesis Examples 1 to 3 and the methacrylate copolymer of Synthesis Example 4 according to the amounts in Table 1 were respectively dissolved in a mixture of 0.03 g of triphenyl sulfonium (TPS) nonaflate and 17 g of PGMEA/EL mixed in a weight ratio of 6/4. Then, 2 mg of triethanolamine was added thereto and completely dissolved, preparing respective resist compositions.

### Comparative Example 1

A resist composition was prepared according to the same method as in Examples 1 to 6, except for using 1 g of the methacrylate copolymer of Synthesis Example 4.

Resolution Evaluation

The resist compositions were filtered with a 0.1 gm-thick membrane filter.

Next, the resist compositions were coated to be 140 nm thick on a silicon wafer treated with HMDS or organic BARC (AR46, Rohm & Haas Co.) at 600 Å, and then soft-baked (SB) at a temperature of 110° C. for 60 seconds and exposed to light by using an ArF scanner (0.93 NA, σ=0.75), followed by post-exposure bake (PEB) at a temperature of 110° C. for 60 seconds and then developing in a 2.38 wt % TMAH solution for 60 seconds. The results are shown in Table 1.

Etching Resistance Evaluation

The resist compositions were evaluated regarding etching characteristics in a reactive ion etching (RIE) method under a CF₄ gas condition (composition: 100 W of power, 5 Pa of pressure, flow rate of 30 ml/min). Herein, the etching rate of a poly(hydroxystyrene) polymer having reference value of 1 as a resist for KrF was normalized as a reference. The results are shown in Table 1.

Adherence Evaluation

In order to evaluate adherence of the resist compositions of Examples 1 to 6 and Comparative Example 1, they were dropped on a bare silicon wafer to measure a contact angle (C/A). The measurements are shown in Table 1. In general, a smaller C/A denotes a better adherence characteristic.

TABLE 1

| | | | | Contact |
|---|---|---|---|---|
| | Polymer composition | | Etching | Angle |
| | (mole ratio) | Resolution | Resistance | (°) |
| Example 1 | (a) Synthesis Example-2 | 70 nm | 1.04 | 72.1 |
| | (m:n = 4:6) 0.2 g | | | |
| | (b) Synthesis Example-4 | | | |
| | (l:m:n = 4:4:2) 0.8 g | | | |
| Example 2 | (a) Synthesis Example-2 | 70 nm | 1.08 | 72.5 |
| | (m:n = 4:6) 0.15 g | | | |
| | (b) Synthesis Example-4 | | | |
| | (l:m:n = 4:4:2) 0.85 g | | | |
| Example 3 | (a) Synthesis Example-2 | 70 nm | 1.12 | 72.4 |
| | (m:n = 4:6) 0.1 g | | | |
| | (b) Synthesis Example-4 | | | |
| | (l:m:n = 4:4:2) 0.9 g | | | |
| Example 4 | (a) Synthesis Example-3 | 70 nm | 1.01 | 72.5 |
| | (m:n = 7:3) 0.2 g | | | |
| | (b) Synthesis Example-4 | | | |
| | (l:m:n = 4:4:2) 0.8 g | | | |
| Example 5 | (a) Synthesis Example-3 | 70 nm | 1.03 | 72.2 |
| | (m:n = 7:3) 0.15 g | | | |
| | (b) Synthesis Example-4 | | | |
| | (l:m:n = 4:4:2) 0.85 g | | | |
| Example 6 | (a) Synthesis Example-3 | 80 nm | 1.09 | 72.3 |
| | (m:n = 7:3) 0.1 g | | | |
| | (b) Synthesis Example-4 | | | |
| | (l:m:n = 4:4:2) 0.9 g | | | |
| Comparative | (b) Synthesis Example-4 | 80 nm | 1.21 | 74.1 |
| Example 1 | (l:m:n = 4:4:2) 1 g | | | |

Referring to Table 1, a resist composition according to an embodiment included a naphthol copolymer and an acryl copolymer, had a clear line and space pattern ranging from 70 to 90 nm, and also had excellent etching resistance and adherence.

As described above, a resist composition according to an embodiment may exhibit excellent resistance for dry etching and excellent adherence to an underlayer. In addition, it may exhibit excellent lithography performance in a lithography process using light in an ultrashort wavelength region of EUV of 13.5 nm as well as an ArF region of 193 nm. A composition according to an embodiment may include a first polymer including a repeating unit represented by a predetermined chemical formula, a second polymer including a repeating unit represented by a predetermined chemical formula, a photoacid generator (PAG), and a solvent.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A resist composition, comprising:
a first polymer including a repeating unit having the following Chemical Formula 1 and a repeating unit having the following Chemical Formula 2;
a second polymer including a repeating unit having the following Chemical Formula 3, a repeating unit having the following Chemical Formula 4, and a repeating unit having the following Chemical Formula 5;
a photoacid generator; and
a solvent, 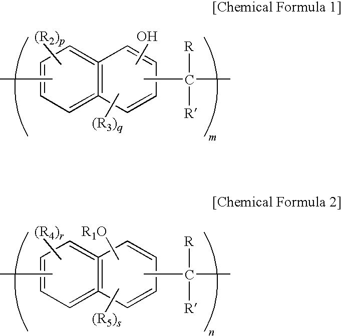
wherein, in the above Chemical Formulae 1 and 2, R₁ is a C4 to C20 acid-labile group, R₂ to R₅ are independently hydrogen or an alkyl, p, q, r, and s are independently an integer ranging from 1 to 3, R and R′ are independently hydrogen or an alkyl, and m and n are mole ratios of the repeating units, m/(m+n) being about 0.1 to 1, 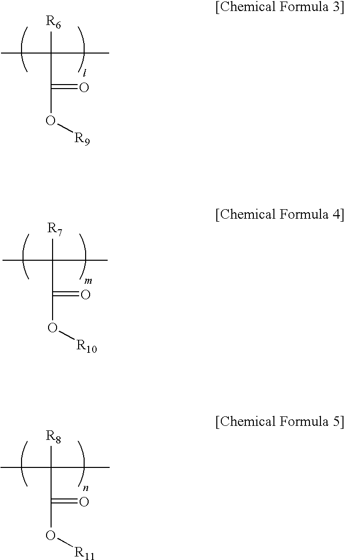
wherein, in the above Chemical Formulae 3 to 5, R₆ to R₈ are independently hydrogen or methyl, R₉ is a C4 to C20 acid-labile group, R₁₀ is a lactone-derived group, R₁₁ is hydrogen or an alkyl or cycloalkyl including a polar functional group selected from among a hydroxy, a carboxyl, and a combination thereof, and l, m and n are mole ratios of the repeating units, 1/(l+m+n) being about 0.1 to about 0.5, m/(l+m+n) being about 0.3 to about 0.5, and n/(l+m+n) being in the range of about 0.1 to about 0.4.

2. The resist composition as claimed in claim 1, wherein the first polymer has a weight average molecular weight (Mw) of about 3,000 to about 20,000.

3. The resist composition of claim 1, wherein the acid-labile group R₉ is norbornyl, isobornyl, cyclodecanyl, adamantyl, norbornyl having a lower alkyl substituent, isobornyl having a lower alkyl substituent, cyclodecanyl having a lower alkyl substituent, adamantyl having a lower alkyl substituent, alkoxycarbonyl, alkoxycarbonyl alkyl, amyloxycarbonyl, amyloxycarbonyl alkyl, 2-tetrahydropyranyloxycarbonyl alkyl, 2-tetrahydrofuranyloxycarbonyl alkyl, a tertiary alkyl, or an acetal.

4. The resist composition of claim 1, wherein the acid-labile group R₉ is 2-methyl-2-norbornyl, 2-ethyl-2-norbornyl, 2-methyl-2-isobornyl, 2-ethyl-2-isobornyl, 8-methyl-8-tricyclodecanyl, 8-ethyl-8-tricyclodecanyl, 2-methyl-2-adamantyl, 2-ethyl-2-adamantyl, 2-propyl-2-adamantyl, t-butoxycarbonyl, t-butoxycarbonylmethyl, t-amyloxycarbonyl, t-amyloxycarbonylmethyl, 1-ethoxyethoxycarbonylmethyl, 2-tetrahydropyranyloxycarbonylalkyl, 2-tetrahydrofuranyloxycarbonylalkyl, t-butyl, triethylcarbyl, 1-methyl cyclohexyl, 1-ethylcyclopentyl, or t-amyl.

5. The resist composition as claimed in claim 1, wherein:
the lactone-derived group is represented by the following Chemical Formula 6 or 7: 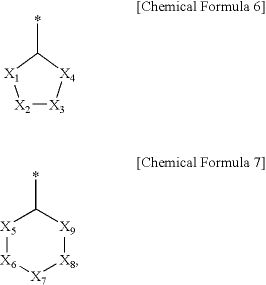
in the above Chemical Formula 6, at least two of X₁ to X₄ are independently CO and O, and the remaining are CR″, where R″ is hydrogen, an alkyl, or an alkylene forming a fused ring with the five-member ring, and
in the above Chemical Formula 7:
at least two of X₅ to X₉ are independently CO and O, the remaining are CR″, where R″ is hydrogen, an alkyl, or an alkylene forming a fused ring with the five-member ring, or
all of X₅ to X₉ are CR″′, where R″′ is hydrogen, an alkyl, an ester-containing alkylene forming a fused ring with the six-member ring, and at least two of R″′ are linked with each other to form a lactone ring.

6. The resist composition as claimed in claim 1, wherein the lactone-derived group is butyrolactonyl, valerolactonyl, 1,3-cyclohexanecarbolactonyl, 2,6-norbornanecarbolacton-5-yl, or 7-oxa-2,6-norbornanecarbolacton-5-yl.

7. The resist composition as claimed in claim 1, wherein the alkyl or cycloalkyl including a polar functional group is 2-hydroxyethyl or 3-hydroxy-1-adamantyl.

8. The resist composition as claimed in claim 1, wherein the second polymer has a weight average molecular weight (Mw) of about 3,000 to about 30,000.

9. The resist composition as claimed in claim 1, wherein the first polymer is included in an amount of about 5 to about 30 wt % based on the sum of the weights of the first polymer and the second polymer.

10. The resist composition as claimed in claim 1, wherein the photoacid generator is included in an amount of about 1 to about 15 parts by weight based on 100 parts by weight of the first polymer and the second polymer.

11. The resist composition as claimed in claim 1, wherein the photoacid generator includes a triarylsulfonium salt, a diaryliodonium salt, a sulfonate, or a mixture thereof.

12. The resist composition as claimed in claim 11, wherein the photoacid generator includes triarylsulfonium triflate, diaryliodonium triflate, triarylsulfonium nonaflate, diaryliodonium nonaflate, succinimidyl triflate, 2,6-dinitrobenzyl sulfonate, or a mixture thereof.

13. The resist composition as claimed in claim 1, wherein the composition further comprises about 0.1 to about 1.0 part by weight of an organic base based on 100 parts by weight of the first polymer and the second polymer.

14. The resist composition as claimed in claim 13, wherein the organic base includes triethylamine, triisobutylamine, trioctylamine, triisodecylamine, triethanolamine, or a mixture thereof.
